(19) United States
(12) Patent Application Publication
(10) Pub. No.: US 2025/0138588 A1
(43) Pub. Date: May 1, 2025

(54) SMART CASING ADAPTED FOR ACCESSORY ATTACHMENT

(71) Applicant: Hooi Chew Chia, Cyberjaya (MY)

(72) Inventor: Hooi Chew Chia, Cyberjaya (MY)

(21) Appl. No.: 18/930,168

(22) Filed: Oct. 29, 2024

(30) Foreign Application Priority Data
Oct. 30, 2023 (MY) PI2023006672

(51) Int. Cl. G06F 1/16; H05K 5/02

(52) U.S. Cl. CPC G06F 1/1656; H05K 5/0204; H05K 5/0221

(57) ABSTRACT

The present invention relates to a smart casing adapted for accessory attachment. Accordingly, the smart casing (100) includes: a) a casing body (110) with a recess (111) configurated to accommodate a portable electronic device (200); b) a holder (120) to accommodate an accessory device (130); characterized in that the casing body (110) provides one or more openings (112a, 112b) for interlocking with the holder (120); wherein the holder (120) has an attachment platform (122) and housing compartment (124), adapted to accommodate and attach the accessory device (130) to the portable electronic device (200) for functionality enhancement.

### FIELD OF INVENTION

The present invention generally relates to a smart casing adapted for accessory attachment and more particularly to a smart casing adapted to accommodate and attach accessory to a portable electronic device for functionality enhancement.

### BACKGROUND OF INVENTION

Digital transformation entails incorporating digital technology throughout a business, fundamentally reshaping how operations are conducted and value is delivered to customers. It is a critical imperative for businesses of all sizes, including small enterprises. In the context of this transformation, employees in enterprises are equipped with multiple Information Technology (IT) devices or gadgets for use during interactions with customers in public settings. For instance, an insurance agent may travel to a customer's residence or meet them in public to facilitate tasks like initiating new insurance policies or processing claims on the spot. Traditionally, these processes necessitate the use of various distinct tools, including a computing device, a portable biometric scanner, and a smart card reader to verify the client's identity.

However, the IT team within the enterprise faces challenges when attempting to procure an integrated or all-in-one portable device from the open market that meets the comprehensive software and hardware requirements for digital transformation. These challenges primarily revolve around compatibility issues with legacy software and applications, constraints related to display size, and the absence of essential peripherals and security features.

The primary limitation of existing portable systems lies in the potential occurrence of technical issues during the assembly of their components. This constant assembly and disassembly have led to a notable decrease in the reliability of these portable devices. Additionally, there is a risk of users forgetting to bring one of these essential components, which can result in delays in critical application processes.

Moreover, these portable systems are typically designed to fit specific models of phones or tablets, lacking the flexibility to accommodate devices of varying sizes once the current model becomes obsolete. These systems rely on contact connectors to establish communication with phones or tablets. Unfortunately, phones and tablets come with a variety of connector types, including Micro USB, USB-C, Apple Lightning, and proprietary connectors. Furthermore, not all phones and tablets fully support USB OTG Mode and USB-C specifications, leading to compatibility issues when switching between different models of phones or tablets. This rigid design has imposed a significant financial burden on users due to ongoing system maintenance expenses.

To address these issues, an increasing number of integrated portable handheld devices and accompanying accessories are being created and made available in the market to fulfil the comprehensive software and hardware needs associated with digital transformation. For example, U.S. Pat. No. 8,483,758 B2 discloses accessories designed for mobile devices. These embodiments encompass an external protective case or holster tailored for mobile electronic devices. Within this external protective case or holster, there are integrated features such as a battery pack, a payment processing device, a television signal receiver, and a modular multi-input/output device.

U.S. Pat. No. 8,749,970 B2 discloses a device designed for attaching to an electronic device is described. This electronic device includes an electrical connector, a back side, a display located on the opposite side of the back side, and lateral sides connecting the back side and the side opposite to the back side. The device includes a first body, an electrical connector, a slot for inserting a Smartcard, a fingerprint reader, and circuitry that is connected to the electrical connector.

U.S. Pat. No. 8,915,361 B2 discloses an apparatus for retaining an electronic device as well as for methods for using the device for the purpose of doing the same. In various instances, the electronic device includes a housing including top and bottom members, and a membrane region configured to facilitate interaction with a biometric scanner on the electronic device is adapted for protecting the device from one or more shock, liquid, dust, snow, and the like. The electronic device may be any suitable electronic device, such as a computer, mobile computer, notebook computer, tablet computer, telephone, personal digital assistant, or the like.

US 2014/0204511 A1 discloses a method for operating an electronic device including an electronic cover device is provided. The method includes coupling the electronic cover device to the electronic device, determining the type of the electronic cover device, and setting an interface based on the type of the electronic cover device.

Nonetheless, numerous integrated portable handheld devices on the market, which come with accompanying accessories, have faced issues related to the breaking or detachment of the attachment or locking mechanism between these portable devices and their accessories. This breaking or detachment problem has led to unreliability, and the design of the attachment or locking mechanism itself is considerably intricate. Consequently, this complexity has contributed to elevated manufacturing complexity and increased production costs. Furthermore, the intricate design can also give rise to usability challenges that may affect the overall user experience and hinder the widespread adoption of the product.

In light of the foregoing, it is desirable to provide a smart casing adapted for accessory attachment, on which it can seamlessly be integrated with the necessary devices, effectively mitigating the above-encountered challenges. The smart casing adapted for accessory attachment of the present invention and its combination of elements thereof will be described and exemplified in the detailed description.

### SUMMARY OF THE INVENTION

The present invention relates to a smart casing adapted for accessory attachment. Accordingly, the smart casing includes: a) a casing body with a recess configurated to accommodate a portable electronic device; b) a holder to accommodate an accessory device; characterized in that the casing body provides one or more openings for interlocking with the holder; wherein the holder has an attachment platform and housing compartment, adapted to accommodate and attach the accessory device to the portable electronic device for functionality enhancement.

In the preferred exemplary of the present invention, it should be noted that one or more openings of the casing body are preferably, but not limited formed as keyhole slots, which include a wider section and a narrower slot, wherein these keyhole slots serve as female slots and function as receptacles for interlocking with the attachment platform of the holder.

Correspondently, the attachment platform of the holder is preferably, but not limited to provide one or more male protrusions configured to fit onto the wider section and smoothly slide into the narrower slot within the keyhole slots of the casing body, creating a secure and interlocking connection.

It will be appreciated that the secure connection can be of other forms including interlocking, robust, or secure engagement, by using screw or other fastening means, that are able to obtain optimal effects and functioning characteristics.

By way of example but not limitation, the one or more openings of the casing body can be of 360° uni-shape design incorporating the keyhole slot interlocking feature, which aids in providing a solution related to display size and angle placement constraints.

Preferably, but not limited to, the 360° uni-shape design offers flexibility for both vertical and horizontal setups or orientations, between the casing body and the holder.

In the preferred exemplary, the portable electronic device may include, but not be limited to a mobile phone, tablet, personal digital assistant (PDA), iPad, laptop, notebook, or any comparable means capable of processing data and performing data transmission.

It should be that the accessory device may encompass wireless or contactless devices, including but not limited to a Bluetooth biometric scanner or fingerprint sensor and card reader.

Optionally, but not limited to, the accessory device may further include other wired, wirelesses, or contactless devices, which include but are not limited to a game player controller module, projector, Bluetooth speaker, video-making kit, microphone LED or live stream selfie light, or other comparable devices.

In one of the preferred exemplary of the accessory device, the wireless or contactless Bluetooth biometric scanner or fingerprint sensor and card reader may include, but are not limited to: a) a circuit board embedded within its body; b) a wireless communication layer enabling wireless connection to the portable electronic device; c) a microcontroller encompasses a microprocessor responsible for handling communication messages; d) a power management circuit and battery charging circuit for managing and supplying electrical power to the internal components; wherein the microprocessor includes one or more universal asynchronous receiver and transmitter (UART) communication ports for connecting the Bluetooth biometric scanner or fingerprint sensor, card reader, wireless transceivers such as Near Field Communication (NFC), wireless module, and secure element.

It should be noted that the microcontroller of the accessory device which encompasses the microprocessor is configured to perform functions including transmitting data, receiving data, clear to send, and requesting to send, facilitating the connection of multiple types of electronic devices.

By way of example but not limitation, the microcontroller may provide an electronic device connection module, a biometric reading module, a card reading module, and a battery module, wherein upon receiving a command triggered by the portable electronic device, the electronic device connection module parses the message and executes either a microcontroller setup process, a card reading process, or a biometric reading process based on the command instructions.

It will be appreciated that the wireless or contactless Bluetooth biometric scanner or fingerprint sensor of the accessory device may further include a battery module configured for managing power distribution from power sources, such as for example, but not limited to a rechargeable battery through the power socket, and capable of monitoring battery status and power level.

The present invention consists of several novel features and a combination of parts hereinafter fully described and illustrated in the accompanying description and drawings, it being understood that various changes in the details may be made without departing from the scope of the invention or sacrificing any of the advantages of the present invention.

### BRIEF DESCRIPTION OF THE DRAWINGS

The present invention will be fully understood from the detailed description given hereinbelow and the accompanying drawings, which are given by way of illustration only, and thus are not limiting to the present invention, wherein:

FIG. 1 shows an exploded view of a smart casing adapted to accommodate and attach accessory to a portable electronic device for functionality enhancement in accordance with the preferred exemplary of the present invention;

FIG. 2 illustrates a partially assembled view of the smart casing of FIG. 1, where the portable electronic device has been omitted from the illustration for clarity and conciseness;

FIG. 3 illustrates the secure interlocking connection between the smart casting and the accessory device according to the preferred embodiment of the present invention;

FIGS. 4a to 5 illustrate the enlarged views and a functional block diagram of a wireless or contactless Bluetooth biometric scanner or fingerprint sensor and card reader of the accessory device, respectively in accordance with one of the preferred exemplary of the present invention.

### DETAILED DESCRIPTION OF THE PREFERRED EMBODIMENTS

The present invention generally relates to a smart casing adapted for accessory attachment, and more particularly to a smart casing adapted to accommodate and attach accessory to a portable electronic device for functionality enhancement. Hereinafter, this specification will describe the present invention according to the preferred exemplary of the present invention. However, it is to be understood that limiting the description to the preferred exemplary of the invention is merely to facilitate discussion of the present invention, and it is envisioned that those skilled in the art may devise various modifications and equivalents without departing from the scope of the appended claims.

The detailed description set forth below in connection with the appended drawings is intended as a description of various exemplary of the present invention and is not intended to represent the only assemblies or embodiments in which the present invention may be practiced. The detailed description includes specific details for the purpose of providing a methodical understanding of the present invention. However, it will be apparent to those skilled in the art that the present invention may be practiced without these specific details. Moreover, the terminology used herein is for the purpose of describing particular embodiments and is not intended to be limited to example embodiments. Acronyms and other descriptive terminology may be used merely for convenience and clarity and are not intended to limit the scope of the invention.

The present invention aims to provide a smart casing adapted for accessory attachment, on which it can seamlessly be integrated with the necessary devices, such as for example but not limited biometric scanner or smart card reader. Accordingly, the present invention seeks to address the above-mentioned issues by providing a smart casing adapted to accommodate and attach accessory to a portable electronic device for functionality enhancement, which is simple in design, cost-effective, and user-friendly, so as to streamline the use of multiple IT gadgets and enhance their reliability and compatibility. It will be appreciated that the present invention would not only reduce manufacturing complexity and production costs but also enhance the overall accessibility and convenience for users.

Moreover, the present invention also provides a solution through a smart holder design that offers flexibility to accommodate a wide range of portable accessory devices with varying sizes and shapes available in the market. This holder boasts a borderless design while incorporating an interlocking feature, allowing it to adapt seamlessly to the diverse sizes and shapes of casings for portable electronic devices, such as for example, but not limited to a mobile phone or tablet. The present invention effectively resolves the challenge of interchanging or combining various sizes and shapes of the said portable devices. Consequently, the holder serves as a platform for housing the accessory devices, including wireless or contactless devices, such as for example, but not limited to a Bluetooth biometric scanner or fingerprint sensor, and card reader, creating an all-inclusive integrated solution.

It should be noted that the wireless or contactless communication design established between the said portable electronic devices (e.g. mobile phone or tablet) and the accessory devices (e.g. Bluetooth biometric scanner or fingerprint sensor, and card reader) effectively resolves compatibility issues, such as Universal Serial Bus (USB) interface variations, size and thickness constraints of phones and tablets, and variations in phone and tablet connector types and positions. This feature contributes significantly in addressing both software and hardware compatibility concerns, as Bluetooth specifications are universally adopted across portable electronic devices, encompassing mobile phones, tablets, and laptops.

Furthermore, the present invention introduces a 360° uni-shape design with a keyhole slot interlocking mechanism, which aids in overcoming limitations related to display size and angle placement constraints. This is particularly relevant because users often have limited options when sourcing solutions from a single provider. Another feature of the present invention is that its ability to address the challenge of setting up multiple peripherals when they are in the form of individual components. The invention consolidates these integrated peripherals into a single component, the portable accessory devices (e.g. Bluetooth biometric scanner or fingerprint sensor, and card reader), establishing a wireless or contactless means of communication with the portable electronic devices (e.g. mobile phone or tablet). This contactless connection effectively eliminates wear and tear issues associated with contact interfaces, resulting in the highest level of reliability and robustness for peripherals.

To achieve the above-mentioned, the smart casing adapted to accommodate and attach accessory to a portable electronic device for functionality enhancement according to the preferred mode of carrying out the present invention will now be described in accordance with the accompanying drawings in FIGS. 1 to 5, either individually or in any combination thereof.

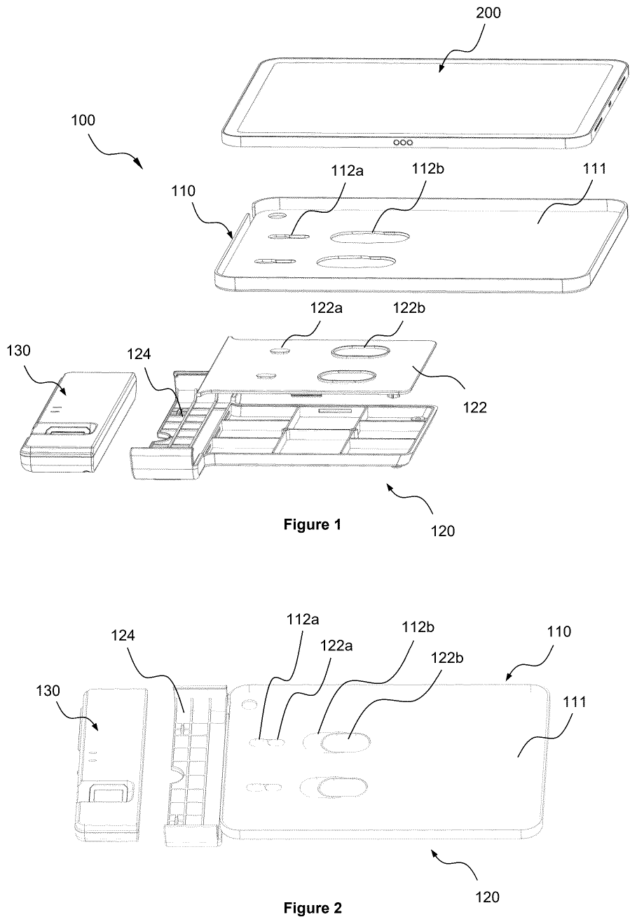

Referring to FIGS. 1 and 2, the smart casing (100) adapted for accessory attachment generally includes a casing body (110), a holder (120) having attachment platform (122) and housing compartment (124), and an accessory device (130). Accordingly, the smart casing (100) has the casing body (110) with a recess (111) configurated to accommodate a portable electronic device (200); whereas the holder (120) is provided to accommodate the accessory device (130).

It should be noted that the casing body (110) of the present invention provides one or more openings (112a, 112b) for interlocking with the holder (120). The holder (120) has an attachment platform (122) and housing compartment (124), which is adapted to accommodate and attach the accessory device (130) to the portable electronic device (200) for functionality enhancement.

In the preferred exemplary of the present invention, it is important to highlight that one or more openings (112a, 112b) of the casing body (110) are preferably, but not limited formed as keyhole slots, which include a wider section and a narrower slot, wherein these keyhole slots serve as female slots and function as receptacles for interlocking with the attachment platform (122) of the holder (120). Accordingly, one or more openings (112a, 112b) of the casing body (110) designed as keyhole slots. These keyhole slots are thoughtfully shaped with a wider section followed by a narrower slot, serving a dual purpose as female slots and acting as receptacles for securely interlocking with the attachment platform (122) of the holder (120).

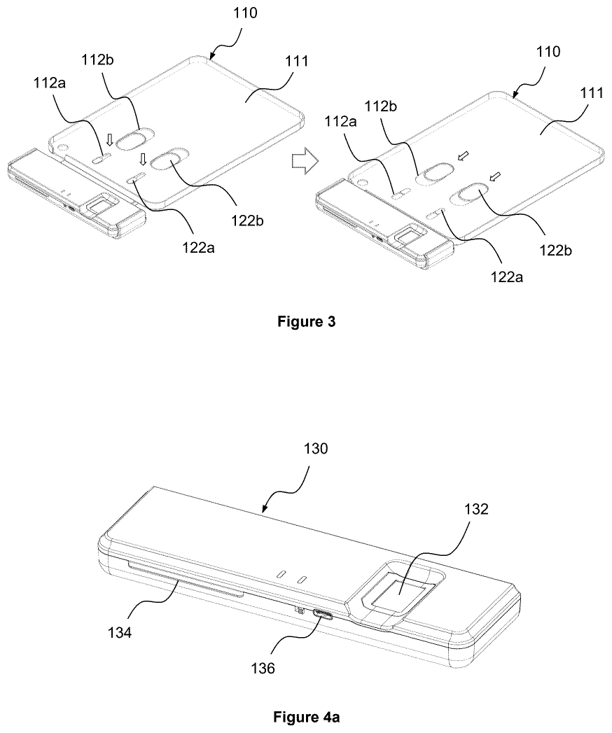

Correspondently, the attachment platform (122) of the holder (120) is preferably, but not limited to provide one or more male protrusions (122a, 122b) configured to fit onto the wider section and smoothly slide into the narrower slot within the keyhole slots of the casing body (110), creating a secure and interlocking connection (see FIG. 3). Accordingly, the attachment platform (122) of the holder (120) is preferably designed to incorporate one or more male protrusions (122a, 122b). These protrusions are thoughtfully configured to align with the wider section and seamlessly glide into the narrower slot within the keyhole slots of the casing body (110), forming a robust and secure interlocking connection.

By way of example but not limitation, the one or more openings (112a, 112b) of the casing body (110) can be of 360° uni-shape design incorporating the keyhole slot interlocking feature, which aids in providing a solution related to display size and angle placement constraints. More specifically, the 360° uni-shape design offers flexibility for both vertical and horizontal setups or orientations, between the casing body (110) and the holder (120). Accordingly, without restricting the possibilities, the one or more openings (112a, 112b) within the casing body (110) can adopt a 360° uni-shape design that includes the keyhole slot interlocking feature. Said openings (112a, 112b) of the casing body (110) are not limited to a specific setup or orientation but are crafted to have a 360-degree circular shape. This circular shape includes the keyhole slot interlocking feature that allows for versatile placement of the accessory device (130), accommodating different angles and display sizes. Accordingly, the accessory device (130) can be attached to the casing body (110) from various directions, giving flexibility in terms of display size and the angle at which it is positioned. The design covers both vertical and horizontal setups or orientations, allowing for a wide range of placement possibilities of between casing body (110) and the holder (120). This feature is beneficial for ensuring that the accessory fits well and can be used effectively, regardless of the specific requirements of the electronic device it's paired with. Thus, this design choice effectively addresses challenges related to display size and angle placement constraints. The 360° uni-shape can be a pear shape, where the bottom hole is larger than the top hole. The pear-shaped holes in the casing body allow the round shape from the attachment platform of the holder to slide from the larger hole to the smaller hole in a direction perpendicular of pear-shaped. This interlocking effect is achieved in all 360 degree orientations.

It will be appreciated that the female keyhole slots and the male protrusions as above-mentioned, although exemplary, will be used herein in describing the possible constituents that may be used by the present invention. However, other forms of interlocking, robust, or secure engagement, such as for example, but not limited to, screw or other fastening means, that are able to obtain optimal effects and functioning characteristics may also be contemplated. As such, the female keyhole slots and the male protrusions as described herein should not be construed as limiting in any way.

In the preferred exemplary, the portable electronic device (200) may include a variety device, such as for example, but not be limited to a mobile phone, tablet, personal digital assistant (PDA), iPad, laptop, notebook, or any comparable means capable of processing data and performing data transmission. Additionally, it is important to highlight that the accessory device (130) may encompass a diverse range of wireless or contactless devices, including but not limited to a Bluetooth biometric scanner or fingerprint sensor (132) and card reader (134). Furthermore, the accessory device (130) may optionally, but not limited to include other wired, wirelesses, or contactless devices, such as for example, but are not limited to a game player controller module, projector, Bluetooth speaker, video-making kit, microphone LED or live stream selfie light, or other comparable devices.

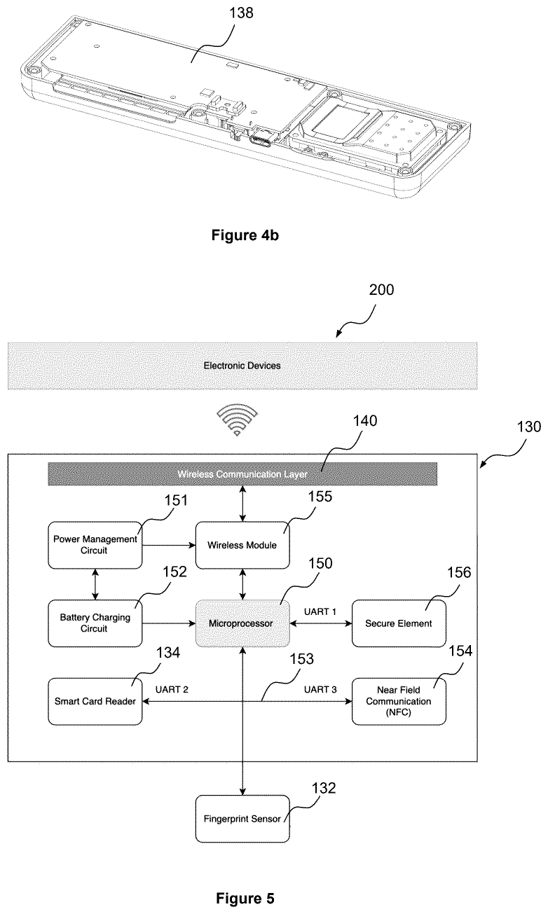

FIGS. 4a to 5 show one of the preferred exemplary of the accessory device (130), the wireless or contactless Bluetooth biometric scanner or fingerprint sensor (132) and card reader (134) may include, but are not limited to: a) a circuit board (138) embedded within its body; b) a wireless communication layer (140) enabling wireless connection to the portable electronic device (200); c) a microcontroller encompasses a microprocessor (150) responsible for handling communication messages; d) a power management circuit (151) and battery charging circuit (152) for managing and supplying electrical power to the internal components; wherein the microprocessor (150) includes one or more universal asynchronous receiver and transmitter (UART) communication ports (153) for connecting the Bluetooth biometric scanner or fingerprint sensor (132), card reader (134), wireless transceivers such as Near Field Communication (NFC) (154), wireless module (155), and secure element (156).

It should be noted that the microcontroller of the accessory device (130) which encompasses the microprocessor (150) is configured to perform functions including transmitting data, receiving data, clear to send, and requesting to send, facilitating the connection of multiple types of electronic devices. Accordingly, the microcontroller within the accessory device (130), which includes the microprocessor (150), is designed to carry out various functions, including data transmission, data reception, clearance for sending data (CTS), and requesting data transmission (RTS). This configuration allows for the seamless connection of a wide range of electronic devices.

By way of example but not limitation, the microcontroller may provide an electronic device connection module, a biometric reading module, a card reading module, and a battery module, wherein upon receiving a command triggered by the portable electronic device (200), the electronic device connection module parses the message and executes either a microcontroller setup process, a card reading process, or a biometric reading process based on the command instructions. Accordingly, the microcontroller may offer an electronic device connection module, a biometric reading module, a card reading module, and a battery module. When it receives a command initiated by the portable electronic device (200), the electronic device connection module interprets the message and performs specific tasks according to the command instructions. This may involve executing a microcontroller setup process, initiating a card reading process, or conducting a biometric reading process, depending on the nature of the command.

It will be appreciated that the wireless or contactless Bluetooth biometric scanner or fingerprint sensor (132) of the accessory device (130) may further include a battery module configured for managing power distribution from power sources, such as for example, but not limited to a rechargeable battery through the power socket (136), and capable of monitoring battery status and power level. Accordingly, the wireless or contactless Bluetooth biometric scanner or fingerprint sensor (132) within the accessory device (130) may incorporate a battery module designed to oversee the distribution of power from various sources. This includes, but is not limited to, a rechargeable battery connected through the power socket (136). Additionally, this battery module has the capability to monitor the status of the battery and its current power level.

The accessory device (130) such as the Bluetooth biometric scanner or fingerprint sensor (132) and card reader (134) as above-described, although exemplary, will be used herein in describing the possible constituents that may be used by the present invention. However, other forms of accessory devices including, but are not limited to wired, wirelesses or contactless devices such as for example, but not limited to a game player controller module, projector, Bluetooth speaker, video-making kit such as microphone LED or live stream selfie light, or other comparable devices that are able to obtain different technical effects and desired functioning characteristics may also be contemplated. As such, the accessory device (130) such as Bluetooth biometric scanner or fingerprint sensor (132) and card reader (134) as described herein should not be construed as limiting in any way.

During operation, users have the capability to initiate the wireless or contactless functions of the Bluetooth biometric scanner or fingerprint sensor (132) and card reader (134) within the accessory device (130) through their portable electronic device (200). Once biometric and identity data has been gathered, this information is transmitted to their portable electronic device (200) via the accessory device's circuit board (138). In cases where the portable electronic device (200) is online or connected to the internet, the collected data can be securely relayed to a server for the purposes of authentication and verification. Alternatively, if internet connectivity is unavailable or for enhanced security measures, the portable electronic device (200) can directly compare the obtained biometric information with the data stored on the user's personal identity (ID) card. Accordingly, the portable electronic device (200) can instruct biometric sensor to verify user live fingerprint with the data stored on the user's personal identify (ID) card. This versatile operation ensures both connectivity and security options for the user in various scenarios.

In a more practical example, practical use or application of the present invention, insurance companies may employ the integrated device Software Development Kit (SDK) within their mobile applications. This technology enables insurance agents to enhance their fieldwork significantly. Equipped with a mobile tablet integrated with this smart and versatile casing, holder, and wireless biometric smart card reader, agents can meet clients in public settings. During these encounters, agents can provide an efficient on-the-spot policy application experience by employing personal identity (ID) card verification. This verification process leverages the minutiae data stored within the client's personal ID card, comparing it to their live fingerprint. This procedure is seamlessly facilitated through a mobile application on the tablet, which commands the wireless biometric smart card reader to read the ID card and the fingerprint scanner to verify the client's live fingerprint.

Furthermore, the application can effortlessly extract client details from their personal ID cards, streamlining the submission process and ensuring a smooth and secure interaction between the agent and client in public spaces.

It should be noted that the components or parts used to carry out the aforementioned invention is illustrative and exemplary only of how the invention can be implemented, and are not restrictive or limiting to the invention. One ordinary skill in the art would recognize that the components or parts used herein may be altered in a manner so as to obtain different optimal effects or desired operating characteristics. As such, the above-described should not be construed as limiting, but as the best mode contemplated by the inventor for carrying out the invention, and yet should be viewed as a starting point for further development and exploration.

The word “exemplary” is used herein to mean serving as an example, instance, or illustration. Any embodiment described herein as “exemplary” is not necessarily to be construed as preferred or advantageous over other embodiments. Likewise, the term “embodiment” of an assembly, method, system, apparatus, device, or article of manufacture does not require that all embodiments of the invention include the described components, structure, features, functionality, processes, advantages, benefits, or modes of operation. As such, the present invention can be implemented in various ways, and the specific embodiments described are not meant to be limiting or prescriptive.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Also, as used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements, and/or components, but do not preclude the presence or addition of one or more other features, integers, steps, operations, elements, components, and/or groups thereof.

The invention being thus described, it will be obvious that the same may be varied in many ways. Such variations are not to be regarded as a departure from the principle and scope of the invention, and all such modifications as would be obvious to one skilled in the art are intended to be included within the scope of the following claims.

1. A smart casing adapted for accessory attachment, wherein the smart casing (100) includes:
a) a casing body (110) with a recess (111) configured to accommodate a portable electronic device (200); and
b) a holder (120) to accommodate an accessory device (130), characterized in that the casing body (110) provides one or more openings (112a, 112b) for interlocking with the holder (120), wherein the holder (120) has an attachment platform (122) and housing compartment (124) adapted to accommodate and attach the accessory device (130) to the portable electronic device (200) for functionality enhancement.

2. The smart casing according to claim 1, wherein the one or more openings (112a, 112b) of the casing body (110) are formed as keyhole slots which include a wider section and a narrower slot, the keyhole slots serving as female slots and functioning as receptacles for interlocking with the attachment platform (122) of the holder (120).

3. The smart casing according to claim 2, wherein the attachment platform (122) of the holder (120) is provided with one or more male protrusions (122a, 122b) configured to fit onto the wider section and smoothly slide into the narrower slot within the keyhole slots of the casing body (110), creating a secure and interlocking connection.

4. The smart casing according to claim 3, wherein the secure connection can be of other forms including interlocking, robust, or secure engagement, by using screw or other fastening means, that are able to obtain optimal effects and functioning characteristics.

5. The smart casing according to claim 2, wherein the one or more openings (112a, 112b) of the casing body (110) can be a 360° uni-shape design incorporating the keyhole slot interlocking feature, which aids in providing a solution related to display size and angle placement constraints.

6. The smart casing according to claim 5, wherein the 360° uni-shape design offers flexibility for both vertical and horizontal setups or orientations between the casing body (110) and the holder (120).

7. The smart casing according to claim 1, wherein the portable electronic device (200) comprises a means for processing data and performing data transmission.

8. The smart casing according to claim 1, wherein the accessory device (130) comprises a wireless or contactless device.

9. The smart casing according to claim 8, wherein the accessory device (130) is a game player controller module, a projector, a Bluetooth speaker, a video-making kit, or a microphone LED or live stream selfie light.

10. The smart casing according to claim 8, wherein the wireless or contactless device is a wireless or contactless Bluetooth biometric scanner or fingerprint sensor (132) or card reader (134) and includes:
a) a circuit board (138) embedded within a body of the accessory device;
b) a wireless communication layer (140) enabling wireless connection to the portable electronic device (200);
c) a microcontroller encompasses a microprocessor (150) responsible for handling communication messages; and
d) a power management circuit (151) and battery charging circuit (152) for managing and supplying electrical power to the internal components,
wherein the microprocessor (150) includes one or more universal asynchronous receiver and transmitter (UART) communication ports (153) for connecting the Bluetooth biometric scanner or fingerprint sensor (132), card reader (134), and a wireless transceiver.

11. The smart casing according to claim 10, wherein the microcontroller of the accessory device (130) which encompasses the microprocessor (150) is configured to perform functions selected from transmitting data, receiving data, clearing to send, requesting to send, and facilitating the connection of multiple types of electronic devices.

12. The smart casing according to claim 11, wherein the microcontroller provides an electronic device connection module, a biometric reading module, a card reading module, and a battery module, wherein upon receiving a command triggered by the portable electronic device (200) the electronic device connection module parses the message and executes either a microcontroller setup process, a card reading process, or a biometric reading process based on the command instructions.

13. The smart casing according to claim 10, wherein the wireless or contactless Bluetooth biometric scanner or fingerprint sensor (132) of the accessory device (130) includes a battery module configured for managing power distribution from a power source and capable of monitoring battery status and power levels.

14. The smart casing according to claim 7, wherein the means for processing data and performing data transmission is selected from the group consisting of a mobile phone, a tablet, a personal digital assistant (PDA), a laptop computer, and a notebook computer, or any comparable means capable of processing data and performing data transmission.

15. The smart casing according to claim 8, wherein the accessory device is a Bluetooth biometric scanner or fingerprint sensor (132) or a card reader (134).

16. The smart casing according to claim 13, wherein the power source comprises a rechargeable battery.
